(19) United States
(12) Patent Application Publication
(10) Pub. No.: US 2026/0068579 A1
(43) Pub. Date: Mar. 5, 2026

(54) GAS COOLING COVER FOR AN EXHAUST LINE OF A SUBSTRATE PROCESSING SYSTEM

(71) Applicant: LAM RESEARCH CORPORATION, Fremont, CA (US)

(72) Inventors: Andrew BORTH, Newberg, OR (US); Sean M. DONNELLY, Portland, OR (US)

(21) Appl. No.: 19/107,160

(22) PCT Filed: Aug. 18, 2023
(86) PCT No.: PCT/US2023/030564

§ 371 Date: Feb. 27, 2025

Related U.S. Application Data
(60) Provisional application No. 63/404,582, filed on Sep. 8, 2022.

(51) Int. Cl. H01L 21/67; H01J 37/32

(52) U.S. Cl. CPC H01L 21/67017; H01J 37/32862

(57) ABSTRACT

A gas cooling cover for an exhaust connector of a substrate processing system includes a first cover portion configured for arrangement around a first portion of the exhaust connector of the substrate processing system and including a first body defining a first gas plenum and a second gas plenum. A first gas inlet is arranged on an outer surface of the first body and in fluid communication with the first gas plenum. A first plurality of nozzles is arranged on an inner surface of the first cover portion and in fluid communication with the first gas plenum. A first plurality of exhaust ports is arranged on the inner surface of the first cover portion and configured to direct gas located between the first cover portion and the first portion of the exhaust connector to the second gas plenum of the first body. WO

### CROSS-REFERENCE TO RELATED APPLICATIONS

This application claims the benefit of U.S. Provisional Application No. 63/404,582, filed on Sep. 8, 2022. The entire disclosure of the application referenced above is incorporated herein by reference.

### FIELD

The present disclosure relates to substrate processing systems, and more particularly to a gas cooling cover for an exhaust line of a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. The substrate treatments may include deposition, etching, cleaning, and other treatments. Example processes that may be performed on a substrate include, but are not limited to, chemical vapor deposition (CVD), atomic layer deposition (ALD), conductor etch, rapid thermal processing (RTP), ion implant, physical vapor deposition (PVD), and/or other etch, deposition, or cleaning processes.

A substrate may be arranged on a substrate support (such as a pedestal or an electrostatic chuck (ESC)) in a processing chamber of the substrate processing system. During processing, gas mixtures (such as precursors or etch gases) may be introduced into the processing chamber using a showerhead (or other gas delivery device) and plasma may be used to initiate chemical reactions. Reactants are evacuated from the processing chamber and delivered to a facility exhaust system.

An exhaust line connects the processing chamber to a valve and a pump. Over time, reactants build up on inner surfaces of the exhaust line and need to be cleaned. During maintenance, remote plasma may be supplied to the exhaust line to remove the buildup. The remote plasma is very hot (>1000° C.), which may damage the exhaust line and/or nearby seals unless cooling is used.

### SUMMARY

A gas cooling cover for an exhaust connector of a substrate processing system includes a first cover portion configured for arrangement around a first portion of the exhaust connector of the substrate processing system and including a first body defining a first gas plenum and a second gas plenum. A first gas inlet is arranged on an outer surface of the first body and in fluid communication with the first gas plenum. A first plurality of nozzles is arranged on an inner surface of the first cover portion and in fluid communication with the first gas plenum. A first plurality of exhaust ports is arranged on the inner surface of the first cover portion and configured to direct gas located between the first cover portion and the first portion of the exhaust connector to the second gas plenum of the first body.

In other features, a second cover portion is configured for arrangement around a second portion of the exhaust connector and for connection to the first cover portion and includes a second body defining a first gas plenum and a second gas plenum. A second gas inlet is arranged on an outer surface of the second body and in fluid communication with the first gas plenum of the second body. A second plurality of nozzles is arranged on an inner surface of the second cover portion and in fluid communication with the first gas plenum. A second plurality of exhaust ports is arranged on the inner surface of the second cover portion and configured to direct gas located between the second cover portion and the second portion of the exhaust connector to the second gas plenum of the second body.

In other features, a first plurality of spacers arranged on the inner surface of the first portion of the first body to maintain spacing between the gas cooling cover and the exhaust connector. The first body of the first cover portion further includes a first outer wall partially defining the second gas plenum of the first body. The first outer wall includes a third plurality of exhaust ports to receive exhaust gas from outlets of the first plurality of exhaust ports

In other features, the third plurality of exhaust ports are misaligned relative to outlets of the first plurality of exhaust ports. The second body of the second cover portion includes an arcuate body portion and an arcuate bracket. The arcuate body portion and the arcuate bracket are configured for attachment around a remote plasma clean (RPC) inlet of the exhaust connector.

In other features, the arcuate body portion includes a first arcuate flange arranged on one side thereof. The arcuate bracket includes second and third arcuate flanges arranged on one side thereof and a gap between the second and third arcuate flanges to allow heated gas to exit. The gas cooling cover is manufactured using additive manufacturing. Additive manufacturing involves depositing a material to additively build up a component using a printable material rather than starting from a block of material and machining the contours of the component. The gas cooling cover is made of a printable material selected from a group consisting of a metal alloy, ceramic, polymer, polymer mixed with particles, and polymer mixed with reinforcing fibers. The gas cooling cover is made of printable aluminum alloy.

In other features, first ends of the first cover portion and the second cover portion are attached around the exhaust connector using a fastener. Second ends of the first cover portion and the second cover portion are attached around the exhaust connector using a spring fastener.

An exhaust system for a substrate processing chamber comprises an exhaust connector including one or more exhaust lines configured to connect to one or more outlets of a processing chamber, and an outlet configured to connect to a valve. A gas cooling cover is arranged around the exhaust connector and including a plurality of nozzles and a plurality of exhaust ports. The gas cooling cover is configured to receive cooling gas, to supply the cooling gas through the plurality of nozzles onto the exhaust connector to cool the exhaust connector, and to remove heated gas located between the gas cooling cover and the exhaust connector through the plurality of exhaust ports.

In other features, the gas cooling cover is manufactured using additive manufacturing. The gas cooling cover is made of a printable material selected from a group consisting of metal alloy, ceramic, polymer, polymer and particles, and polymer and reinforcing fibers.

In other features, the gas cooling cover includes a first cover portion and a second cover portion. First ends of the first cover portion and the second cover portion are attached together around the exhaust connector. Second ends of the first cover portion and the second cover portion are attached together around the exhaust connector.

In other features, the first cover portion includes a first body defining a first gas plenum and a second gas plenum. A first gas inlet is arranged on an outer surface of the first body and in fluid communication with the first gas plenum. First ones of the plurality of nozzles arranged on an inner surface of the first cover portion and in fluid communication with the first gas plenum. First ones of the plurality of exhaust ports arranged on the inner surface of the first cover portion and configured to direct gas located between the first cover portion and the exhaust connector to the second gas plenum of the first body. The second cover portion includes a second body defining a first gas plenum and a second gas plenum. A second gas inlet is arranged on an outer surface of the second body and in fluid communication with the first gas plenum of the second body. Second ones of the plurality of nozzles arranged on an inner surface of the second cover portion and in fluid communication with the first gas plenum. Second ones of the plurality of exhaust ports arranged on the inner surface of the second cover portion and configured to direct gas located between the second cover portion and the exhaust connector to the second gas plenum of the second body.

In other features, a first plurality of spacers arranged on the inner surface of the first body and a second plurality of spacers arranged on the inner surface of the second body. The first plurality of spacers and the second plurality of spacers maintain spacing between the gas cooling cover and the exhaust connector.

In other features, the first body of the first cover portion further includes a first outer wall partially defining the second gas plenum of the first body. The second body of the second cover portion further includes a second wall partially defining the second gas plenum of the first body. The first outer wall includes third ones of the plurality of exhaust ports to receive exhaust gas from outlets of the first ones of the plurality of exhaust ports. The second wall includes fourth ones of plurality of exhaust ports to receive exhaust gas from outlets of the second ones of the plurality of exhaust ports.

In other features, the second body of the second cover portion includes an arcuate body portion and an arcuate bracket. The arcuate body portion and the arcuate bracket are configured for attachment around a remote plasma clean (RPC) inlet of the exhaust connector. The arcuate body portion includes a first arcuate flange arranged on one side thereof. The arcuate bracket includes second and third arcuate flanges arranged on one side thereof and a gap between the second and third arcuate flanges to allow heated gas to exit.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system according to the present disclosure;

FIG. 2 is a perspective view of an exhaust connector arranged between a processing chamber and a valve and a pump;

FIG. 3 is a perspective view of an example of a gas cooling cover for an exhaust connector according to the present disclosure;

FIG. 4 is an inside view of an example of a first cover portion of the gas cooling cover according to the present disclosure;

FIG. 5 is a simplified cross-sectional view of an example of first and second gas plenums of the first cover portion according to the present disclosure; and

FIG. 6 is an inside view of an example of a second cover portion of the gas cooling cover according to the present disclosure.

In the drawings, reference numbers may be reused to identify similar and/or identical elements.

### DETAILED DESCRIPTION

One or more exhaust lines or fore lines of an exhaust connector are connected to one or more outlets of the processing chamber. In some examples, the exhaust connector combines multiple exhaust lines into a single exhaust line that is connected to an inlet of a valve and pump. In other examples, a single exhaust line may be used.

During operation of the substrate processing system, reactants are evacuated from the processing chamber through the exhaust connector and some of the reactants build up on inner surfaces of the exhaust connector. After processing substrates for a while, maintenance is performed to remove the reactants from the inner surfaces of the exhaust connector.

The exhaust connector may include a remote plasma clean (RPC) inlet located near a junction of the two exhaust lines. In other examples, the RPC gases may enter the exhaust lines upstream from the exhaust connector. In other examples, cleaning species that do not require disassociation to be sufficiently reactive may be used instead of plasma.

During operation of the processing chamber and/or during maintenance such as RPC, the exhaust connector is heated. The exhaust connector may need to be cooled (or heated) to prevent damage. For example, the remote plasma may be heated to a temperature greater than 1000° C. Other major heat sources may include exothermic chemical reactions between the plasma and the buildup, and recombination of radicals on interior surfaces of the exhaust connector.

Cooling tubes (such as copper tubes) carrying fluid (such as process cooled water) have been attached to an outer surface of the exhaust connector to remove heat from the exhaust connector. However, the cooling tubes can leak fluid and cause contamination and/or electrical problems. If the fluid is not flowing through the tubes at a sufficient flow rate, boiling of the fluid can occur. The tubes are also difficult to package.

Instead of using cooling tubes carrying cooling fluid, a substrate processing system according to the present disclosure includes a gas cooling cover or jacket arranged around a portion of the exhaust connector. An inner surface of the gas cooling cover is spaced from an outer surface of the exhaust connector to allow cooling gas to exchange heat with the exhaust connector. Cooling gas such as air is supplied to a first gas plenum of the gas cooling cover. Cooling gas in the first gas plenum flows through nozzles (located on an inner surface of the gas cooling cover) and onto the exhaust connector. The inner surface of the gas cooling cover also includes exhaust ports including through holes to receive the heated gas and output the heated gas to a second gas plenum of the gas cooling cover. While cooling gas is used to cool the exhaust connector in some examples, the cover can also receive heated gas to heat a component that is below a desired temperature.

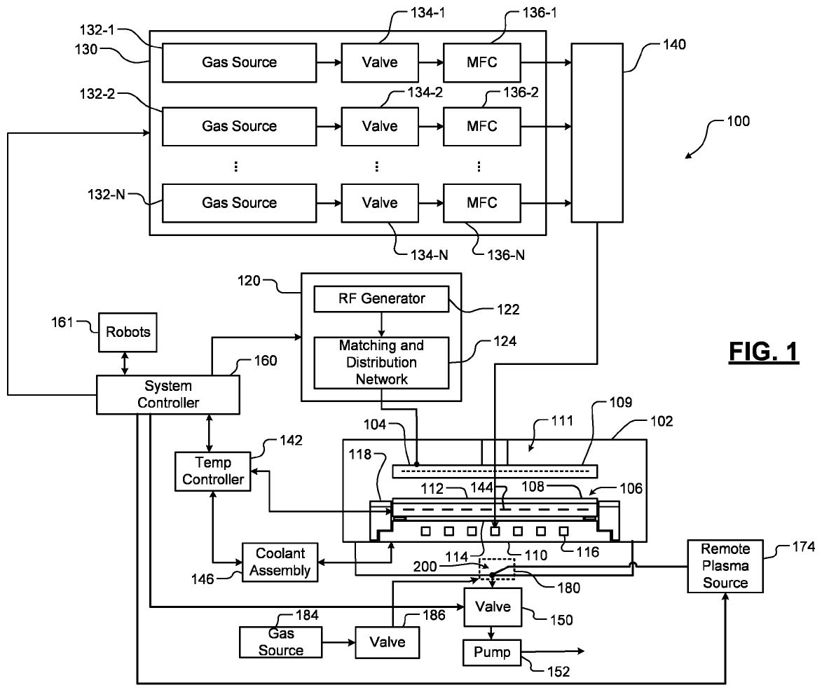

Referring now to FIG. 1, a substrate processing system 100 includes a processing chamber 102 that encloses components of the substrate processing system 100 and contains RF plasma. The processing chamber 102 includes an upper electrode 104 and a substrate support 106, which may be an electrostatic chuck (ESC). During operation, a substrate 108 is arranged on the substrate support 106. While a specific example of the substrate processing system 100 and processing chamber 102 are shown as an example, the principles of the present disclosure may be applied to other types of substrate processing systems and chambers, such as a substrate processing system that uses remote plasma generation and delivery (e.g., using a plasma tube, a microwave tube), etc.

A gas distribution device 111 distributes process gases. For example only, the upper electrode 104 may be combined with a showerhead 109 (acting as the gas distribution device 111). The showerhead 109 may include a stem portion including one end connected to a top surface of the processing chamber 102. A base portion is generally cylindrical, includes a gas plenum, and extends radially outwardly from an opposite end of the stem portion at a location that is spaced from the top surface of the processing chamber 102. A substrate-facing surface or faceplate of the base portion of the showerhead 109 includes holes through which process gas or purge gas flows. Alternately, the upper electrode 104 may include a conducting plate and the process gases may be introduced in another manner.

The substrate support 106 includes a baseplate 110 that is conductive and acts as a lower electrode. The baseplate 110 supports a top plate 112, which may be formed of ceramic. In some examples, the top plate 112 may include one or more heating layers, such as a ceramic multi-zone heating plate. The one or more heating layers may include one or more heating elements, such as conductive traces, as further described below.

A bond layer 114 is disposed between and bonds the top plate 112 to the baseplate 110. The baseplate 110 may include one or more coolant channels 116 for flowing coolant through the baseplate 110. In some examples, the substrate support 106 may include an edge ring 118 arranged to surround an outer perimeter of the substrate 108.

An RF generating system 120 generates and outputs an RF voltage to one of the upper electrode 104 and the lower electrode (e.g., the baseplate 110 of the substrate support 106). The other one of the upper electrode 104 and the baseplate 110 may be DC grounded, AC grounded or floating. For example only, the RF generating system 120 may include an RF voltage generator 122 that generates the RF voltage that is fed by a matching and distribution network 124 to the upper electrode 104. In other examples, the RF voltage is provided to the baseplate 110. In other examples, the plasma may be generated inductively or remotely. Although the RF generating system 120 corresponds to a capacitively coupled plasma (CCP) system, the principles of the present disclosure may also be implemented in other suitable systems, such as transformer coupled plasma (TCP) systems, inductively coupled plasma (ICP) systems, CCP cathode systems, remote microwave plasma generation and delivery systems, etc.

A gas delivery system 130 includes one or more gas sources 132-1, 132-2, . . . , and 132-N (referred to collectively as gas sources 132), where N is an integer greater than zero. The gas sources supply one or more gas mixtures. The gas sources may also supply purge gas. Vaporized precursor may also be used. The gas sources 132 are connected by valves 134-1, 134-2, . . . , and 134-N (referred to collectively as valves 134) and mass flow controllers 136-1, 136-2, . . . , and 136-N (referred to collectively as mass flow controllers 136) to a manifold 140. A second set of valves (not shown) may be arranged between the mass flow controllers 136 and the manifold 140. An output of the manifold 140 is fed to the processing chamber 102. For example only, the output of the manifold 140 is fed to the showerhead 109.

A temperature controller 142 may be connected to heating elements, such as thermal control elements (TCEs) 144, arranged in the top plate 112. For example, the heating elements may include, but are not limited to, macro heating elements corresponding to respective zones in a multi-zone heating plate and/or an array of micro heating elements disposed across multiple zones of a multi-zone heating plate. The temperature controller 142 may be used to control the heating elements to control a temperature of the substrate support 106 and the substrate 108.

The temperature controller 142 may communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the substrate support 106.

A valve 150 and a pump 152 are connected to an exhaust line 148 and are used to evacuate reactants from the processing chamber 102. A controller 160 may be used to control components of the substrate processing system 100. One or more robots 161 may be used to deliver substrates onto, and remove substrates from, the substrate support 106. A remote plasma source 174 selectively delivers remote plasma to exhaust lines connecting the processing chamber to the valve 150 to clean the exhaust lines. A valve (not shown) may be arranged between the remote plasma source 174 and the valve 150. A gas cooling cover 180 is arranged around a portion of an exhaust connector 200. A gas source 184 and a valve 186 may be used to supply cooling gas such as air or another cooling gas to the gas cooling cover 180.

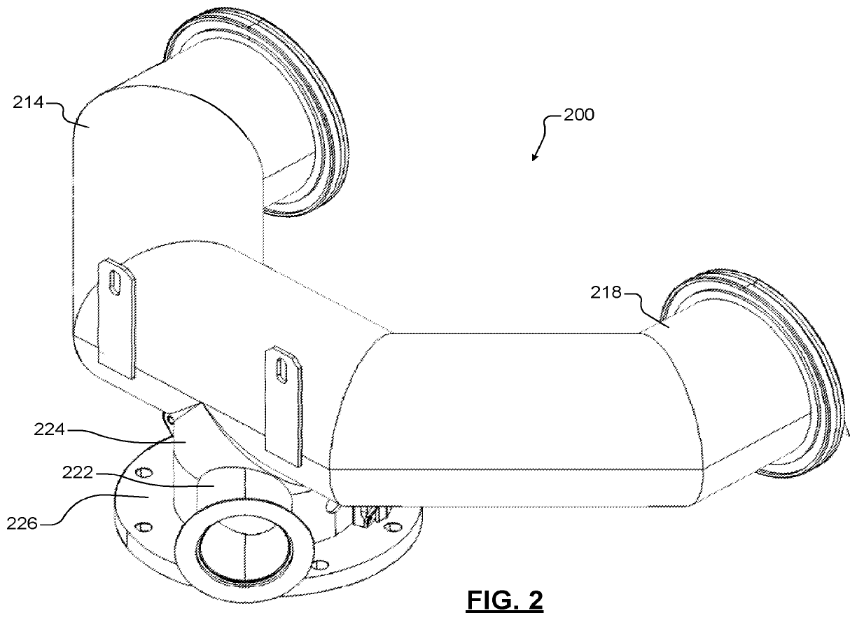

Referring now to FIG. 2, an example of an exhaust connector 200 is shown for purposes of illustration. In this example, the exhaust connector includes a first exhaust line 214, a second exhaust line 218, and an RPC inlet 222. As noted above, the exhaust connector 200 may have different configurations. For example, the exhaust connector 200 may include one or more exhaust lines and the RPC inlet 222 may be omitted.

In this example, the first exhaust line 214 and the second exhaust line 218 converge into an outlet exhaust line 224 that is connected to a flange 226. The flange 226 connects the exhaust connector 200 to the valve 150 (e.g., a pendulum valve) and the pump 152 (e.g., a turbo molecular pump). A seal (not shown) may be arranged between the flange 226 and the valve 150. The exhaust connector 200 further includes a remote plasma cleaning (RPC) inlet 222 to the outlet exhaust line 224. During RPC, remote plasma is supplied to the exhaust connector 200 to clean the exhaust lines. Significant heating of the exhaust connector 200 occurs and cooling is required to prevent damage to the exhaust connector 200 and/or the seal.

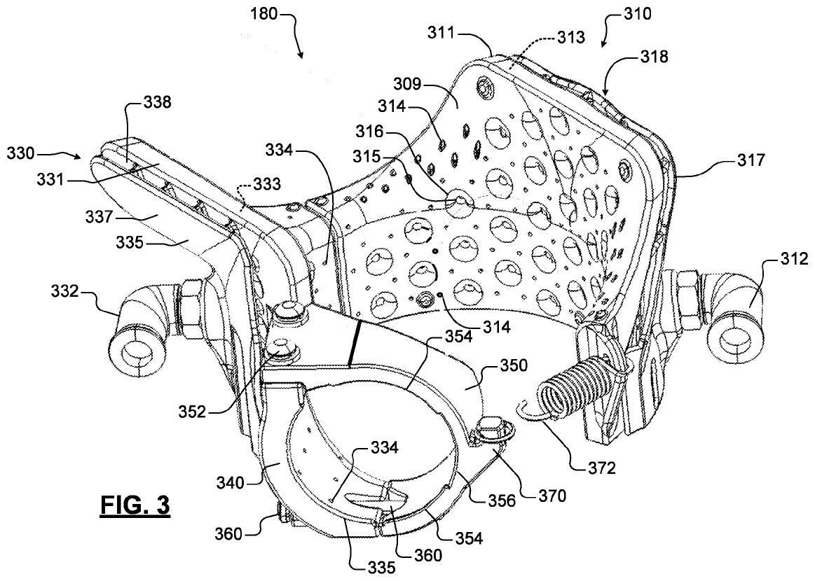

Referring now to FIG. 3, the gas cooling cover 180 further includes a first cover portion 310 and a second cover portion 330 that are arranged around the outlet exhaust line 224 of the exhaust connector 200 and fastened together. Shapes of the first cover portion 310 and the second cover portion 330 can be asymmetric or symmetric (not shown). Shapes of the first cover portion 310 and the second cover portion 330 are varied depending upon the corresponding shapes of the exhaust connector 200 and other components arranged nearby.

The first cover portion 310 includes a body 311 including one or more inlets 312 arranged on an outer surface thereof to receive cooling gas. The body 311 defines a first gas plenum 313 that receives the cooling gas from the inlet 312. An inner surface 309 of the body 311 includes outlets of nozzles 314 to supply jets of cooling gas from the first gas plenum 313 onto the exhaust connector 200. In some examples, the nozzles 314 include a through hole. The inner surface of the body 311 further includes inlets to exhaust ports 316 (including through holes 315 arranged in a conical cavity) to receive heated gas. As will be described further below, the first gas plenum 313 is in fluid communication with the nozzles 314 and is isolated from exhaust gas flowing through the through holes 315. An outer wall 317 of the body 311 partially encloses the second gas plenum 318 and includes outlets of exhaust ports (shown below) that are misaligned with outlets (not shown) of the through holes 315 to reduce noise.

The second cover portion 330 includes a body 331 including one or more inlets 332 arranged on an outer surface 335 thereof to receive cooling gas such as pressurized air. The body 331 defines a first gas plenum 333 that receives the cooling gas from the inlet 332. An inner surface of the body 331 includes outlets of nozzles 334 to supply cooling gas from the first gas plenum 313 onto the exhaust connector 200. The inner surface of the body 331 further includes inlets of exhaust ports including through holes (not shown) to receive heated gas and to deliver the heated gas to a second gas plenum 338. The first gas plenum 333 is in fluid communication with the nozzles 334 and is isolated from heated gas flowing from the through holes 315 to the second gas plenum 338. An outer wall 337 of the body 331 is spaced from the inner portion of the body 331, partially encloses the second gas plenum 338, and includes exhaust ports (shown below) that are misaligned with outlets (not shown) of the through holes 315.

The body 331 of the second cover portion 330 further includes an arcuate body portion 340 that is configured to fit around a first arcuate portion of an outer surface of the RPC inlet 222 (when used). An arcuate bracket 350 is configured to fit around a second arcuate portion of the outer surface of the RPC inlet 222. The bracket 350 is connected to the arcuate body portion 340 to engage the outer surface of the RPC inlet 222.

An inner surface of the arcuate body portion 340 is spaced from the outer surface of the RPC inlet 222 and includes nozzles 334 that are configured to supply cooling gas between the gas cooling cover 180 and the RPC inlet 222. In some examples, fasteners 352 and 360 are used to connect the bracket 250 to the arcuate body portion 340 around the RPC inlet 222. In some examples, the arcuate body portion 340 and the arcuate bracket 350 include arcuate flanges 335 and 354, respectively, extending radially outwardly on one or both sides thereof to contain cooling gas between the arcuate body portion 340 and the arcuate bracket 350 and to maintain spacing with the RPC inlet. An open or flange-less portion 356 is located on the bracket 350 between the arcuate flanges 335 and 354 to allow heated gas to escape. The arcuate bracket 350 further includes a projection 370 to allow a spring fastener 372 to connect aligned ends of the second cover portion 330 and the first cover portion 310 together.

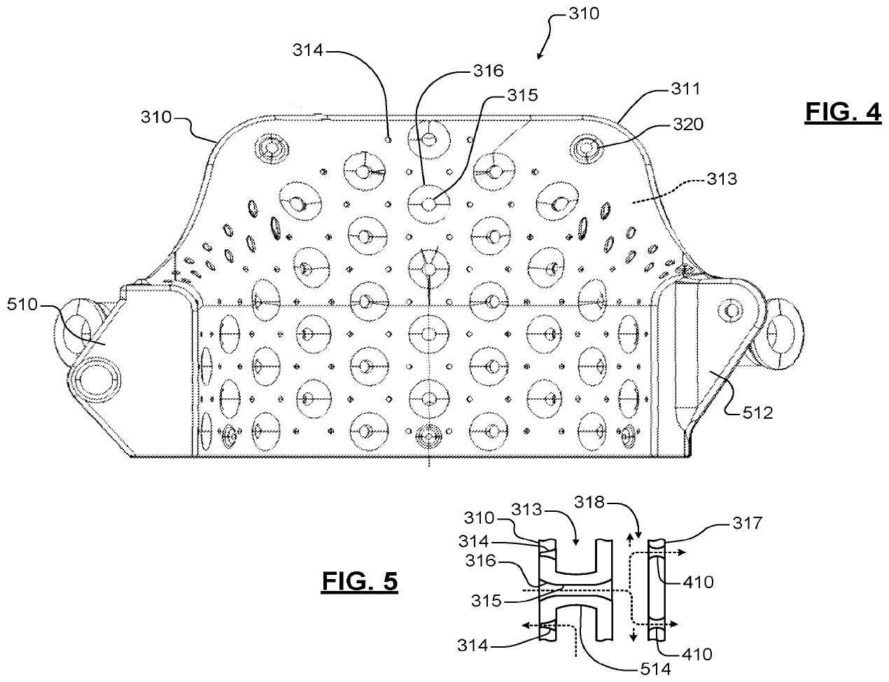

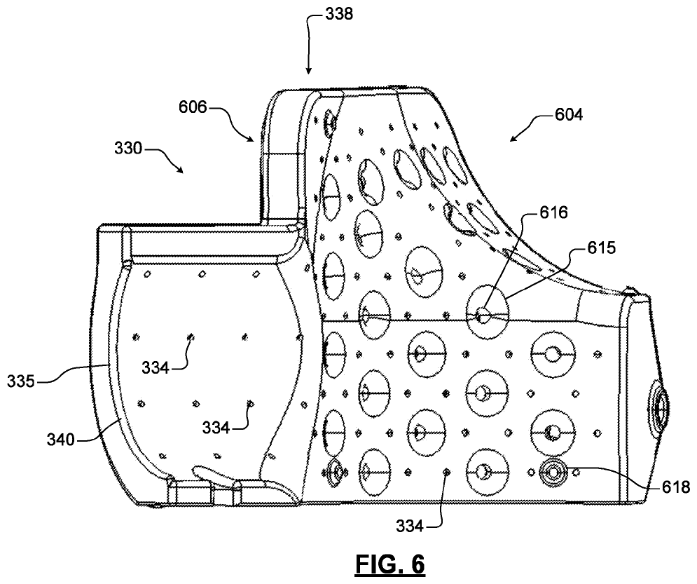

Referring now to FIGS. 4 and 5, the inner surface of the first portion of the body 311 of the first cover portion 310 is shown. In FIG. 4, spacers 320 are arranged at a plurality of locations on an inner surface of the first cover portion 310 to maintain spacing between the inner surface of the body 311 and the exhaust connector 200 and to ensure sufficient cooling gas flow. End face 510 mates with a corresponding face of the second cover portion 330. End faces 510 and 512 include mounting holes to receive fastener 360 and spring fastener 372, respectively.

In FIG. 5, the first gas plenum 313 supplies cooled gas through the nozzles 314 and onto adjacent portions of the exhaust connector 200. The cooled supply gas is heated by the exhaust connector 200 and then returns through nearby exhaust ports 316 and through holes 315. The through holes 315 pass through columns 514 arranged in the first gas plenum 313 to prevent mixing of cooled supply gas and heated gas. The heated gas enters the second gas plenum 318 and then passes through the exhaust openings 410 passing though the outer wall 317 and/or though gaps between the outer wall 317 and the body 311 at top and bottom surfaces of the gas cooled cover 180.

Referring now to FIG. 6, the inner surface of the first portion of the body 331 of the second cover portion 330 is shown. As can be appreciated, a shape of the second cover portion 330 is different than a shape of the first cover portion 310 due to the asymmetric shape of the exhaust connector 200. The second cover portion 330 includes an arcuate portion 604 extending upwardly and then downwardly into a stepped portion 606 to accommodate a shape of the RPC inlet 222 and the connector 220. Spacers 618 are arranged at a plurality of locations to maintain a predetermined distance between the second cover portion 330 and the exhaust connector 200 to allow gas flow. Exhaust ports 615 and through holes 616 return heated gas to the second gas plenum 318.

In some examples, the gas cooling cover is made using additive manufacturing. In some examples, the gas cooling cover is made of a printed material selected from a group consisting of a printed metal alloy (such as printed aluminum), unreinforced polymer, reinforced polymer (such as glass particles or reinforcing fibers such as glass fiber, carbon fiber, etc.), printed ceramic, or another suitable material. In some examples, a plurality of nozzles is arranged around the exhaust ports. For example, 4 to 8 nozzles (e.g., 6 nozzles) surround each of the exhaust ports (to the extent that sufficient space is available) and the nozzles may be shared by adjacent exhaust ports.

The gas cooling cover 180 provides impingement cooling directly onto the complex surface of the exhaust connector 200. The exhaust gas is locally routed back through the gas cooling cover 180. Since gas flow needs to be high, the offset exhaust ports located on the outer walls of the cooling gas cover reduce ambient noise.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A gas cooling cover for an exhaust connector of a substrate processing system, comprising:
a first cover portion configured for arrangement around a first portion of the exhaust connector of the substrate processing system and including:
a first body defining a first gas plenum and a second gas plenum;
a first gas inlet arranged on an outer surface of the first body and in fluid communication with the first gas plenum;
a first plurality of nozzles arranged on an inner surface of the first cover portion and in fluid communication with the first gas plenum; and
a first plurality of exhaust ports arranged on the inner surface of the first cover portion and configured to direct gas located between the first cover portion and the first portion of the exhaust connector to the second gas plenum of the first body.

2. The gas cooling cover of claim 1, further comprising a second cover portion configured for arrangement around a second portion of the exhaust connector and for connection to the first cover portion and including:
a second body defining a first gas plenum and a second gas plenum;
a second gas inlet arranged on an outer surface of the second body and in fluid communication with the first gas plenum of the second body;
a second plurality of nozzles arranged on an inner surface of the second cover portion and in fluid communication with the first gas plenum; and
a second plurality of exhaust ports arranged on the inner surface of the second cover portion and configured to direct gas located between the second cover portion and the second portion of the exhaust connector to the second gas plenum of the second body.

3. The gas cooling cover of claim 1, further comprising a first plurality of spacers arranged on the inner surface of the first portion of the first body to maintain spacing between the gas cooling cover and the exhaust connector.

4. The gas cooling cover of claim 1, wherein the first body of the first cover portion further includes a first outer wall partially defining the second gas plenum of the first body.

5. The gas cooling cover of claim 4, wherein the first outer wall includes a third plurality of exhaust ports to receive exhaust gas from outlets of the first plurality of exhaust ports

6. The gas cooling cover of claim 5, wherein the third plurality of exhaust ports are misaligned relative to outlets of the first plurality of exhaust ports.

7. The gas cooling cover of claim 2, wherein the second body of the second cover portion includes:
an arcuate body portion; and
an arcuate bracket, wherein the arcuate body portion and the arcuate bracket are configured for attachment around a remote plasma clean (RPC) inlet of the exhaust connector.

8. The gas cooling cover of claim 7, wherein:
the arcuate body portion includes a first arcuate flange arranged on one side thereof; and
the arcuate bracket includes second and third arcuate flanges arranged on one side thereof and a gap between the second and third arcuate flanges to allow heated gas to exit.

9. The gas cooling cover of claim 1, wherein the gas cooling cover is manufactured using additive manufacturing.

10. The gas cooling cover of claim 9, wherein the gas cooling cover is made of a printable material selected from a group consisting of a metal alloy, ceramic, polymer, polymer mixed with particles, and polymer mixed with reinforcing fibers.

11. The gas cooling cover of claim 9, wherein the gas cooling cover is made of printable aluminum alloy.

12. The gas cooling cover of claim 2, wherein:
first ends of the first cover portion and the second cover portion are attached around the exhaust connector using a fastener; and
second ends of the first cover portion and the second cover portion are attached around the exhaust connector using a spring fastener.

13. An exhaust system for a substrate processing chamber, comprising:
an exhaust connector including:
one or more exhaust lines configured to connect to one or more outlets of a processing chamber; and
an outlet configured to connect to a valve; and
a gas cooling cover arranged around the exhaust connector and including a plurality of nozzles and a plurality of exhaust ports,
wherein the gas cooling cover is configured to receive cooling gas, to supply the cooling gas through the plurality of nozzles onto the exhaust connector to cool the exhaust connector, and to remove heated gas located between the gas cooling cover and the exhaust connector through the plurality of exhaust ports.

14. The exhaust system of claim 13, wherein the gas cooling cover is manufactured using additive manufacturing.

15. The exhaust system of claim 13, wherein the gas cooling cover is made of a printable material selected from a group consisting of metal alloy, ceramic, polymer, polymer and particles, and polymer and reinforcing fibers.

16. The exhaust system of claim 13, wherein:
the gas cooling cover includes a first cover portion and a second cover portion;
first ends of the first cover portion and the second cover portion are attached together around the exhaust connector; and
second ends of the first cover portion and the second cover portion are attached together around the exhaust connector.

17. The exhaust system of claim 16, wherein:
the first cover portion includes:
a first body defining a first gas plenum and a second gas plenum;
a first gas inlet arranged on an outer surface of the first body and in fluid communication with the first gas plenum;
first ones of the plurality of nozzles arranged on an inner surface of the first cover portion and in fluid communication with the first gas plenum; and
first ones of the plurality of exhaust ports arranged on the inner surface of the first cover portion and configured to direct gas located between the first cover portion and the exhaust connector to the second gas plenum of the first body, and
the second cover portion includes:
a second body defining a first gas plenum and a second gas plenum;
a second gas inlet arranged on an outer surface of the second body and in fluid communication with the first gas plenum of the second body;
second ones of the plurality of nozzles arranged on an inner surface of the second cover portion and in fluid communication with the first gas plenum; and
second ones of the plurality of exhaust ports arranged on the inner surface of the second cover portion and configured to direct gas located between the second cover portion and the exhaust connector to the second gas plenum of the second body.

18. The exhaust system of claim 17, further comprising:
a first plurality of spacers arranged on the inner surface of the first body; and
a second plurality of spacers arranged on the inner surface of the second body,
wherein the first plurality of spacers and the second plurality of spacers maintain spacing between the gas cooling cover and the exhaust connector.

19. The gas cooling cover of claim 17, wherein:
the first body of the first cover portion further includes a first outer wall partially defining the second gas plenum of the first body,
the second body of the second cover portion further includes a second wall partially defining the second gas plenum of the first body,
the first outer wall includes third ones of the plurality of exhaust ports to receive exhaust gas from outlets of the first ones of the plurality of exhaust ports, and
the second wall includes fourth ones of plurality of exhaust ports to receive exhaust gas from outlets of the second ones of the plurality of exhaust ports.

20. The exhaust system of claim 17, wherein the second body of the second cover portion includes:
an arcuate body portion; and
an arcuate bracket,
wherein the arcuate body portion and the arcuate bracket are configured for attachment around a remote plasma clean (RPC) inlet of the exhaust connector,
wherein the arcuate body portion includes a first arcuate flange arranged on one side thereof, and
wherein the arcuate bracket includes second and third arcuate flanges arranged on one side thereof and a gap between the second and third arcuate flanges to allow heated gas to exit.
